(19) United States
(12) Patent Application Publication
(10) Pub. No.: US 2022/0085101 A1
(43) Pub. Date: Mar. 17, 2022

(54) INTEGRATED STRUCTURE OF CRYSTAL RESONATOR AND CONTROL CIRCUIT AND INTEGRATION METHOD THEREFOR

(71) Applicant: NINGBO SEMICONDUCTOR INTERNATIONAL CORPORATION (SHANGHAI BRANCH), Shanghai (CN)

(72) Inventor: Xiaoshan QIN, Ningbo, Zhejiang (CN)

(21) Appl. No.: 17/419,675

(22) PCT Filed: Nov. 5, 2019
(86) PCT No.: PCT/CN2019/115643

§ 371 Date: Jun. 29, 2021

(30) Foreign Application Priority Data
Dec. 29, 2018 (CN) 201811647856.2

(51) Int. Cl. H01L 27/20; H03H 3/02; H03H 9/05; H03H 9/19

(52) U.S. Cl. CPC H01L 27/20; H03H 9/19; H03H 9/0547; H03H 3/02

(57) ABSTRACT

An integrated structure of crystal resonator and control circuit and an integration method therefor. A lower cavity is formed in a device wafer, and an upper cavity is formed in a substrate. A bonding process is then performed to bond the device wafer and the substrate together in such a manner that a piezoelectric vibrator is sandwiched between the device wafer and the substrate, with the lower and upper cavities being located on opposing sides of the piezoelectric vibrator, thus resulting in the formation of the crystal resonator. Moreover, the crystal resonator is brought into electrical connection with the control circuit, achieving integration of the two. This crystal resonator is more compact in size, less power-consuming and easier to integrate with other semiconductor components with a higher degree of integration, compared with traditional crystal resonators.

### TECHNICAL FIELD

The present invention relates to the technical field of semiconductor and, in particular, to an integrated structure of crystal resonator and control circuit and an integration method therefor.

### BACKGROUND

A crystal resonator is a device operating on the basis of inverse piezoelectricity of a piezoelectric crystal. As key components in crystal oscillators and filters, crystal resonators have been widely used to create high-frequency electrical signals for performing precise timing, frequency referencing, filtering and other frequency control functions that are necessary for measurement and signal processing systems.

The continuous development of semiconductor technology and increasing popularity of integrated circuits has brought about a trend toward miniaturization of various semiconductor components. However, it is difficult to integrate existing crystal resonators with other semiconductor components, and also the sizes of the existing crystal resonators are relatively large.

For example, commonly used existing crystal resonators include surface-mount ones, in which a base is bonded with a metal solder (or an adhesive) to a cover to form a hermetic chamber in which a piezoelectric crystal is housed. In addition, electrodes on two sides of the piezoelectric crystal are electrically connected to an associated circuit via solder pads or wires. Further shrinkage of such crystal resonators is difficult, and their electrical connection to the associated circuit by soldering or gluing additionally hinders their miniaturization.

### SUMMARY OF THE INVENTION

It is an object of the present invention to provide a method for integrating a crystal resonator with a control circuit, which overcomes the above described problems with conventional crystal resonators, i.e., a bulky size and difficult integration.

To solve the problem, the present invention provides a method for integrating a crystal resonator with a control circuit, comprising:

providing a device wafer in which the control circuit is formed, and etching the device wafer to form a lower cavity for the crystal resonator;

providing a substrate and etching the substrate to form therein an upper cavity for the crystal resonator at a location in positional correspondence with the lower cavity;

forming a piezoelectric vibrator comprising a top electrode, a piezoelectric crystal and a bottom electrode, which are formed either on the device wafer or on the substrate;

forming a connecting structure on the device wafer or on the substrate; and

bonding the substrate to the device wafer such that the piezoelectric vibrator is situated between the device wafer and the substrate, with the upper and lower cavities being located on opposing sides of the piezoelectric vibrator, and electrically connecting both the top and bottom electrodes of the piezoelectric vibrator to the control circuit through the connecting structure.

It is a further object of the present invention to provide an integrated structure of a crystal resonator and a control circuit, comprising:

a device wafer in which the control circuit and a lower cavity are formed;

a substrate, which is bonded to the device wafer, and in which an upper cavity is formed, the upper cavity having an opening opposing an opening of the lower cavity;

a piezoelectric vibrator comprising a bottom electrode, a piezoelectric crystal and a top electrode, the piezoelectric vibrator disposed between the device wafer and the substrate, with the lower and upper cavities being positioned on opposing sides of the piezoelectric vibrator;

a connecting structure disposed between the device wafer and the substrate, the connecting structure electrically connecting both the bottom and top electrodes of the piezoelectric vibrator to the control circuit.

In the method for integrating a crystal resonator with a control circuit, planar fabrication processes are employed to form the lower and upper cavities in the device wafer and the substrate, respectively, and a bonding process is then performed to bond the substrate and the device wafer together in such a manner that the piezoelectric vibrator is sandwiched between the device wafer and the substrate, with the lower and upper cavities positioned on opposing sides of the piezoelectric vibrator. In this way, the crystal resonator is formed and integrated with the control circuit at the same time.

As such, compared with traditional crystal resonators (e.g., surface-mount ones), in addition to being able to integrate with other semiconductor components with a higher degree of integration, the crystal resonator proposed in the present invention is more compact or miniaturized in size and hence less costly and less power-consuming.

### BRIEF DESCRIPTION OF THE DRAWINGS

FIG. 1 shows a flowchart schematically illustrating a method for integrating a crystal resonator with a control circuit according to Embodiment 1 of the present invention.

FIGS. 2a to 2g are schematic representations of structures resulting from steps in the method according to Embodiment 1 of the present invention.

FIGS. 3a to 3e are schematic representations of structures resulting from steps in a method for integrating a crystal resonator with a control circuit according to Embodiment 3 of the present invention.

In these figures,

100 denotes a device wafer; AA, a device area; 100A, a substrate wafer; 100B, a dielectric layer; 110, a control circuit; 111, a first circuit; 111T, a first transistor; 111C, a first interconnecting structure; 112, a second circuit; 112T, a first transistor; 112C, a first interconnecting structure; 120, a lower cavity; 210, a bottom electrode; 220, a piezoelectric crystal; 230, a top electrode; 300, a substrate; 310, an upper cavity; 410, a first encapsulation layer; 420, a second encapsulation layer; 510, an interconnecting wire; and 520, a conductive plug.

### DETAILED DESCRIPTION

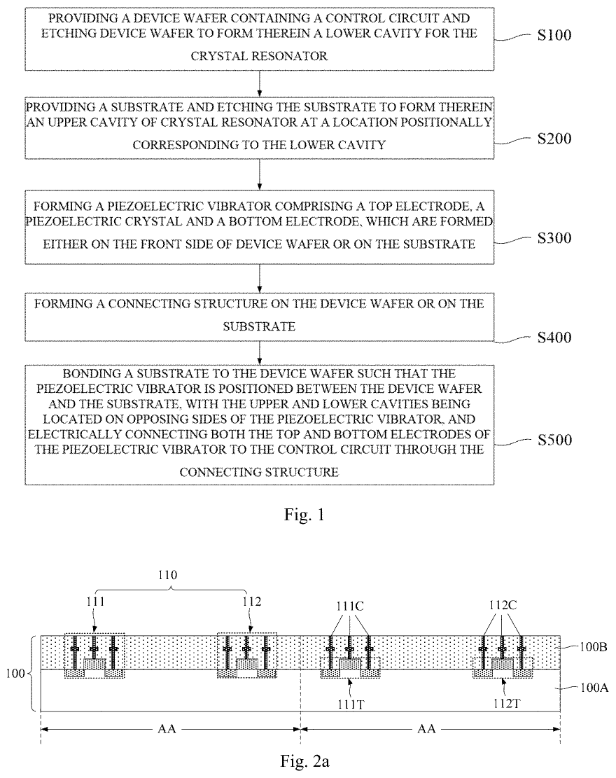

The core idea of the present invention is to provide an integrated structure of a crystal resonator and a control circuit and an integration method therefor, which allow an increased degree of integration and a reduced size of the crystal resonator. FIG. 1 shows a flowchart schematically illustrating a method for integrating a crystal resonator with a control circuit according to an embodiment of the present invention. As shown in FIG. 1, the method for integrating a crystal resonator with a control circuit includes the steps of:

Step S100: providing a device wafer in which a control circuit is formed, and etching the device wafer to form therein a lower cavity for the crystal resonator;

Step S200: providing a substrate and etching the substrate to form therein an upper cavity of the crystal resonator that is in positional correspondence with the lower cavity;

Step S300: forming a piezoelectric vibrator including a top electrode, a piezoelectric crystal and a bottom electrode, which are formed on one of the device wafer and the substrate;

Step S400: forming a connecting structure on the device wafer or the substrate; and

Step S500: positioning the piezoelectric vibrator between the device wafer and substrate, with the upper and lower cavities located on opposing sides of the piezoelectric vibrator, and electrically connecting both the top and bottom electrodes of the piezoelectric vibrator to the control circuit by the connecting structure.

Therefore, with the present invention, planar fabrication processes are utilized to integrate the crystal resonator with the control circuit. This, on the one hand, results in a size reduction of the crystal resonator and, on the other hand, allows an increased degree of integration of the crystal resonator with other semiconductor components.

Specific embodiments of the structure and method proposed in the present invention will be described below in greater detail with reference to the accompanying drawings. Features and advantages of the invention will be more apparent from the following description. Note that the accompanying drawings are provided in a very simplified form not necessarily drawn to exact scale, and their only intention is to facilitate convenience and clarity in explaining the disclosed embodiments.

### Embodiment 1

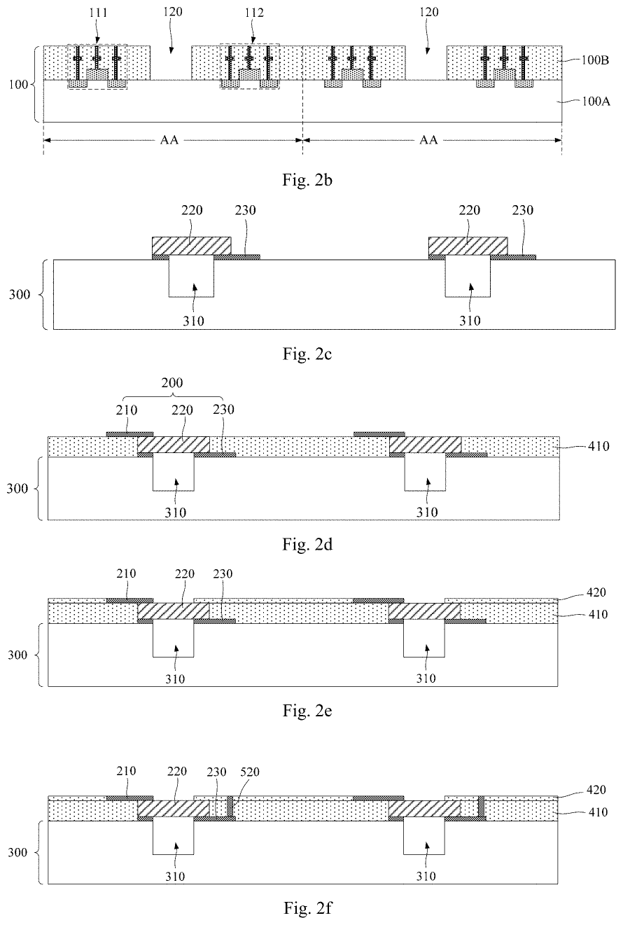

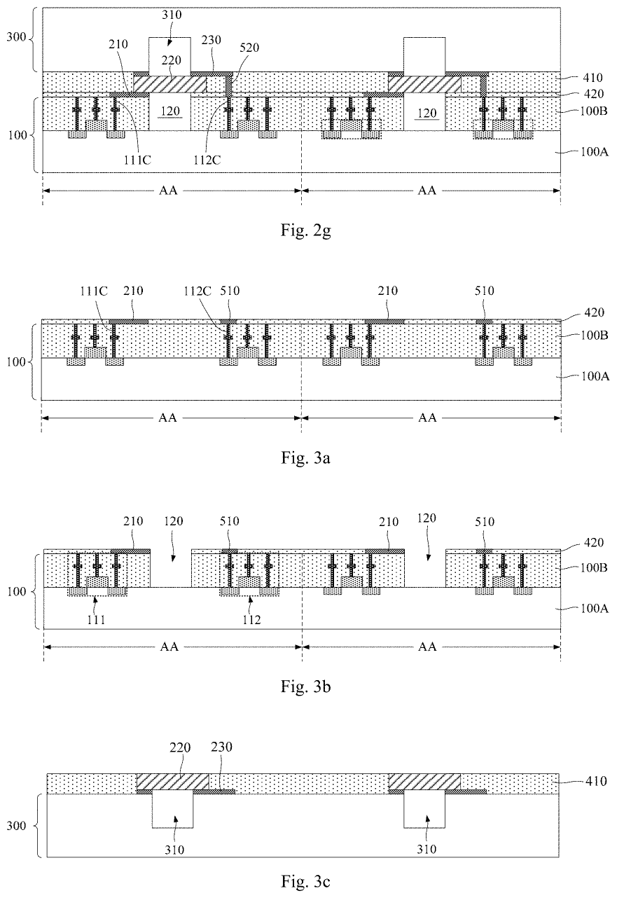

FIGS. 2a to 2g are schematic representations of structures resulting from steps in the method for integrating a crystal resonator with a control circuit according to Embodiment 1 of the present invention. In the following, steps for forming the crystal resonator will be described in detail with reference to the figures.

In step S100, with reference to FIGS. 2a and 2b, a device wafer 100 is provided in which the control circuit 110 is formed, and etched so that a lower cavity 120 for the crystal resonator is formed therein. The formed lower cavity 120 is exposed from a front side of the device wafer 100, and the control circuit 110 is configured to, for example, apply an electrical signal to opposing sides of the subsequently formed piezoelectric crystal.

A plurality of crystal resonators may be formed on the single device wafer 100. Accordingly, there may be a plurality of device areas AA defined in the device wafer 100, each with a crystal resonator and a control circuit 110 being formed therein.

The control circuit 110 may include a first circuit 111 and a second circuit 112. The first and second circuits 111, 112 are configured for electrical connection with top and bottom electrodes on opposing sides of the subsequently formed piezoelectric crystal.

With continued reference to FIG. 2a, the first circuit 111 may include a first transistor 111T and a first interconnecting structure 111C. The first transistor 111T may be buried within the device wafer 100, and the first interconnecting structure 111C may be connected to the first transistor 111T and extend to the front side of the device wafer 100. The first interconnecting structure 111C may include conductive plugs electrically connected respectively to a gate, source and drain of the first transistor 111T.

Similarly, the second circuit 112 may include a second transistor 112T and a second interconnecting structure 112C. The second transistor 112T may be buried within the device wafer 100, and the second interconnecting structure 112C may be connected to the second transistor 112T and extend to the front side of the device wafer 100. The second interconnecting structure 112C may include conductive plugs electrically connected respectively to a gate, source and drain of the second transistor 112T.

A method for forming the control circuit 110 may include:

providing a substrate wafer 100A and forming the first and second transistors 111T, 112T on the substrate wafer 100A; and

then forming a dielectric layer 100B on the substrate wafer 100A to cover the first and second transistors 111T, 112T, and forming the first and second interconnecting structures 111C, 112C, in the dielectric layer 100B, resulting in the formation of the device wafer 100.

In other words, the device wafer 100 includes the substrate wafer 100A and the dielectric layer 100B formed thereon, and the first and second transistors 111T, 112T are both formed on the substrate wafer 100A. Additionally, the dielectric layer 100B covers the first and second transistors 111T, 112T, and the first and second interconnecting structures 111C, 112C are all so formed in the dielectric layer 100B as to extend to the surface of the dielectric layer 100B.

In this embodiment, the substrate wafer 100A may be either a silicon wafer or a silicon-on-insulator (SOI) wafer. In the latter case, the substrate wafer may include a base layer, a buried oxide layer and a top silicon layer, which are sequentially stacked in this order in the direction from a back side 100D to a front side 100U.

With continued reference to FIG. 2b, in this embodiment, the lower cavity 120 is formed in the dielectric layer 100B of the device wafer 100 in the device area AA. The lower cavity 120 may be formed by etching the dielectric layer 100B. The lower cavity 120 may have a depth that is determined, without limitation, as practically required. For example, the lower cavity 120 may either extend only in the dielectric layer 100B or further into the substrate wafer 100A from the dielectric layer 100B.

When the substrate wafer 100A is implemented as an SOI wafer, the etching process for forming the lower cavity may proceed further through a top silicon layer so that the formed lower cavity extends from the dielectric layer down to the buried oxide layer.

It is to be noted that the relative positions of the lower cavity 120 and the first and second circuits shown in the figures are merely for illustration, and in practice, the arrangement of the first and second circuits may depend on the actual circuit lay-out requirements. The present invention is not limited in this regard.

In step S200, with reference to FIG. 2c, a substrate 300 is provided and etched so that an upper cavity 310 of the crystal resonator is formed therein in positional correspondence with the lower cavity 120. The upper cavity 310 may have a depth that is determined, without limitation, as practically required. In a subsequent process for bonding the substrate 300 to the device wafer 100, the upper and lower cavities 310, 120 may be positioned on opposing sides of the piezoelectric vibrator.

On the substrate 300, there may be also defined a plurality of device areas AA corresponding to those in the device wafer 100, and the lower cavity 120 may be formed in a corresponding one of the device areas AA of the device wafer 100.

In step S300, a piezoelectric vibrator including a top electrode, a piezoelectric crystal and a bottom electrode is formed. The top electrode, the piezoelectric crystal and the bottom electrode may be formed either on the front side of the device wafer 100 or on the substrate 300.

In other words, it is possible that the top electrode, the piezoelectric crystal and the bottom electrode in the piezoelectric vibrator are all formed on the front side of the device wafer 100, or on the substrate 300. It is also possible that the bottom electrode of the piezoelectric vibrator is formed on the front side of the device wafer, with the top electrode and piezoelectric crystal of the piezoelectric vibrator being formed sequentially on the substrate. It is still possible that the bottom electrode and the piezoelectric crystal of the piezoelectric vibrator are formed sequentially on the front side of the device wafer, with the top electrode of the piezoelectric vibrator being formed on the substrate.

In this embodiment, the top electrode, piezoelectric crystal and bottom electrode in the piezoelectric vibrator are all formed on the substrate 300. Specifically, a method for forming the piezoelectric vibrator on the substrate 300 may include the steps as follows:

Step 1: Forming the top electrode 230 at a predetermined location on a surface of the substrate 300, as shown in FIG. 2c. In this embodiment, the top electrode 230 surrounds the upper cavity 310. In a subsequent process, the top electrode 230 may be brought into electrical connection with the control circuit 110 and, more exactly, to the second interconnecting structure in the second circuit 112.

Step 2: With continued reference to FIG. 2c, bonding the piezoelectric crystal 220 to the top electrode 230. In this embodiment, the piezoelectric crystal 220 is located above the upper cavity 310, with its peripheral edge portions residing on the top electrode 230. The piezoelectric crystal 220 may be, for example, a quartz crystal plate.

In this embodiment, the upper cavity 310 may be narrower than the piezoelectric crystal 220 so that the piezoelectric crystal 220 can be arranged with its peripheral edge portions residing on the surface of the substrate, thus covering an opening of the upper cavity 310.

However, in other embodiments, the upper cavity may be made up of, for example, a first portion and a second portion. The first portion may be at a deeper position in the substrate than the second portion, and the second portion may be adjacent to the surface of the substrate. Additionally, the first portion may be narrower than the piezoelectric crystal 220, and the second portion may be broader than the piezoelectric crystal. In this way, the piezoelectric crystal 220 may be at least partially received in the second portion, with its peripheral edge portions residing on top edges of the first portion. In addition, it is devisable that the opening of the upper cavity is wider than the piezoelectric crystal.

Further, the top electrode 230 may have an extension laterally extending beyond the piezoelectric crystal 220 thereunder. In a subsequent process, the top electrode 230 may be connected to the second interconnecting structure in the second circuit 112 via the extension.

Step 3: Forming the bottom electrode 210 on the piezoelectric crystal 220, as shown in FIG. 2d. The bottom electrode 210 may be so formed that a central portion of the piezoelectric crystal 220 is exposed therefrom. In a subsequent process, the bottom electrode 210 may be electrically connected to the control circuit 110 and, more exactly, to the first interconnecting structure in the first circuit 111.

Thus, in the control circuit 110, the first circuit 111 is electrically connected to the bottom electrode 210, and the second circuit 112 is electrically connected to the top electrode 230. As such, an electrical signal can be applied to the bottom and top electrodes 210, 230 to create an electric field therebetween, which causes a shape change in the piezoelectric crystal 220 between the top and bottom electrodes 230, 210. The magnitude of the shape change of the piezoelectric crystal 220 depends on the strength of the electric field, and when the electric field between the top and bottom electrodes 230, 210 is inverted, the piezoelectric crystal 520 will responsively change its shape in the opposite direction. Therefore, when the control circuit 110 applies an AC signal to the top and bottom electrodes 230, 210, the piezoelectric crystal 220 will change shape alternately in opposite directions and thus alternately contract and expand due to the change in direction of the electric field. As a result, the piezoelectric crystal 220 will vibrate mechanically.

In this embodiment, a method for forming the bottom electrode 210 on the substrate 300 may include, for example, the steps below.

In a first step, with reference to FIG. 2d, a first encapsulation layer 410 is formed on the substrate 300 to cover the substrate 300, and the piezoelectric crystal 220 is exposed from the first encapsulation layer 410. It is to be noted that, in this embodiment, since the top electrode 230 is formed under the piezoelectric crystal 220, with the extension thereof extending laterally beyond the piezoelectric crystal 220, the first encapsulation layer 410 also covers the extension of the top electrode 230.

In addition, a top surface of the first encapsulation layer 410 may not be higher than that of the piezoelectric crystal 220. In this embodiment, the formation of the first encapsulation layer 410 may involve planarizing the first encapsulation layer 410 so that its top surface is flush with that of the piezoelectric crystal 220.

In a second step, with continued reference to FIG. 2d, the bottom electrode 210 is formed on the surface of the piezoelectric crystal 220. The bottom electrode 210 has an extension extending laterally beyond the piezoelectric crystal 220 on the first encapsulation layer 410. In a subsequent process, the bottom electrode 210 may be connected to the control circuit (more exactly, to the first interconnecting structure in the first circuit 111) via the extension of the bottom electrode.

The bottom and top electrodes 210, 230 may be successively formed, using a thin-film deposition or vapor deposition process, each of a material including silver.

It is to be noted that, in this embodiment, the top electrode 230, the piezoelectric crystal 220 and the bottom electrode 210 are successively formed over the substrate 300 using semiconductor processes. However, in other embodiments, it is also possible to form the top and bottom electrodes on opposing sides of the piezoelectric crystal and then bond the three as a whole onto the substrate.

Optionally, subsequent to the formation of the bottom electrode 210, the method may further include forming a second encapsulation layer on the first encapsulation layer 410 to provide the substrate 300 with a fatter surface that is favorable to the subsequent bonding process.

With reference to FIG. 2e, the second encapsulation layer 420 is formed on the first encapsulation layer 410, and may have a top surface not higher than that of the bottom electrode 210 so that the bottom electrode 210 remains exposed. In this embodiment, the formation of the second encapsulation layer 420 may involve planarizing the second encapsulation layer 420 so that its top surface is flush with that of the bottom electrode 210. Moreover, the central portion of the piezoelectric crystal 220 may also be exposed from the second encapsulation layer 420. In this way, when the substrate 300 is subsequently bonded to the device wafer 100, the central portion of the piezoelectric crystal 220 is in positional correspondence with the lower cavity 120 in the device wafer 100.

In step S400, a connecting structure is formed on the device wafer 100 or on the substrate 300. In a subsequent process, the connecting structure may bring the bottom electrode 210 on the substrate 300 into electrical connection with the control circuit in the device wafer 100 (more exactly, with the first interconnecting structure in the first circuit) and bring the top electrode 230 on the substrate 300 into electrical connection with the control circuit in the device wafer 100 (more exactly, with the second interconnecting structure in the second circuit).

Specifically, the connecting structure may include a first connecting member that connects the first interconnecting structure to the bottom electrode 210 of the piezoelectric vibrator and a second connecting member that connects the second interconnecting structure to the top electrode 230 of the piezoelectric vibrator.

With continued reference to FIG. 2e, in this embodiment, the bottom electrode 210 with its aforementioned extension is exposed at the surface of the second encapsulation layer 420, and the first interconnecting structure in the first circuit is exposed at the top at the surface of the device wafer 100. Therefore, the device wafer 100 and the substrate 300 may be so bonded together that the bottom electrode 210 resides on the surface of the device wafer 100, with a connection being established between its extension and the first interconnecting structure in the first circuit 111. In this case, it can be considered that the extension of the bottom electrode 210 directly forms the first connecting member.

Of course, in other embodiments, it is also possible that the first connecting member is so formed on the device wafer 100 as to be electrically connected to the first interconnecting structure prior to the bonding of the device wafer 100 and the substrate 300, and brought into electrical connection with the bottom electrode 210 during the bonding of the device wafer 100 and the substrate 300. In this case, the first connecting member may include, for example, a rewiring layer, which is connected to the first interconnecting structure and is brought into electrical connection with the bottom electrode 210 during the bonding of the device wafer 100 and the substrate 300.

Referring to FIG. 2f, the top electrode 230 is buried within the first encapsulation layer 410 while the extension of the top electrode 230 may be brought into connection with the second interconnecting structure in the second circuit 112 by the second connecting member.

In this embodiment, subsequent to the successive formation of the top electrode 230 and the piezoelectric crystal 220 on the substrate 300, the second connecting member may be so formed on the substrate 300 as to be electrically connected to the top electrode 230. Specifically, the second connecting member that connects the top electrode 230 to the second circuit 112 may include a conductive plug 520.

The formation of the conductive plug 520 of the second connecting member may include the steps below.

At first, an encapsulation layer is formed on the surface of the substrate 300. In this embodiment, this encapsulation layer is made up of the aforementioned first and second encapsulation layers 410, 420.

Next, a through hole is formed in the encapsulation layer to expose the top electrode 530, and a conductive material is filled in the through hole, resulting in the formation of the conductive plug 520, which is electrically connected at one end to the top electrode 530, in particular, to the extension of the top electrode 530.

In this embodiment, the through hole is formed by sequentially etching the second encapsulation layer 420 and the first encapsulation layer 410, and the conductive plug 520 is then formed by filling a conductive material in the through hole. One end of the conductive plug 520 is electrically connected to the top electrode 230, and the other end of the conductive plug 520 is exposed at the surface of the second encapsulation layer 420. As such, an electrical connection can be established between the other end of the conductive plug 520 and the second interconnecting structure as a result of bonding the substrate 300 to the device wafer 100.

In step S500, with reference to FIG. 2g, the substrate 300 is bonded to the front side of the device wafer 100 such that the piezoelectric vibrator is sandwiched between the device wafer 100 and the substrate 300, with the upper and lower cavities 310, 120 being located on opposing sides of the piezoelectric vibrator 200, resulting in the formation of the crystal resonator. In addition, the top and bottom electrodes 230, 210 of the piezoelectric vibrator 200 are both electrically connected to the control circuit through the connecting structure.

As discussed above, in this embodiment, the device wafer 100 and the substrate 300 are so bonded that, in the control circuit, the first circuit 111 is electrically connected to the bottom electrode 210 by the first connecting member (i.e., the extension of the bottom electrode) and the second circuit 112 is electrically connected to the top electrode 230 by the second connecting member (i.e., the conductive plug 520). In this way, the control circuit can apply an electrical signal to the electrodes sandwiching the piezoelectric crystal 220, which causes the piezoelectric crystal 220 to change its shape and vibrate in the upper and lower cavities 310, 120.

The bonding of the device wafer and the substrate may be accomplished by a method including, for example, applying an adhesive layer to the device wafer 100 and/or to the substrate 300 and bonding the device wafer 100 and the substrate 300 together by means of the adhesive layer. Specifically, an adhesive layer may be applied to the substrate with the piezoelectric crystal formed thereon in such a manner that the surface of the piezoelectric crystal is exposed from a surface of the adhesive layer, and the substrate without the piezoelectric crystal formed thereon may be then bonded to the adhesive layer.

In this embodiment, the piezoelectric vibrator 200 is formed on the substrate 300. Accordingly, the bonding of the device wafer 100 and the substrate 300 may be accomplished by a method including, for example, applying an adhesive layer to the substrate 300 so that the surface of the piezoelectric vibrator 200 is exposed from a surface of the adhesive layer, and then bonding together the substrate 300 and the device wafer 100 by means of the adhesive layer.

Therefore, in this embodiment, the top electrode 230, piezoelectric crystal 220 and bottom electrode 210 of the piezoelectric vibrator 200 are all formed on the substrate 300, and the piezoelectric vibrator 200 covers an opening of the upper cavity 310. In addition, the bonding is so performed that the lower cavity 120 is located on the side of the piezoelectric vibrator 200 away from the upper cavity 310 and the crystal resonator is thus formed. In addition, the crystal resonator is electrically connected to the control circuit in the device wafer 100, achieving the integration of the crystal resonator with the control circuit.

### Embodiment 2

Differing from Embodiment 1, the top electrode 230, piezoelectric crystal 220 and bottom electrode 210 of the piezoelectric vibrator 200 are all formed on the front side of the device wafer 100, and the piezoelectric vibrator 200 covers and closes an opening of the lower cavity 120 in accordance with Embodiment 2. In addition, after the crystal resonator is electrically connected to the control circuit in the device wafer 100, a bonding process is performed so that the upper cavity 310 is located on the side of the piezoelectric vibrator 200 away from the lower cavity 120. Forming the crystal resonator in this way also achieves integration of the crystal resonator with the control circuit.

Specifically, in step S300, the formation of the piezoelectric vibrator on the device wafer 100 may include the steps below.

At first, the bottom electrode 210 is formed at a predetermined location on a surface of the device wafer 100. In this embodiment, the bottom electrode 210 is positioned around the lower cavity 120.

Then, the piezoelectric crystal 220 is bonded to the bottom electrode 210. In this embodiment, the piezoelectric crystal 220 is so bonded above the lower cavity 120 that it covers and closes an opening of the lower cavity 120, with its peripheral edge portions residing on the bottom electrode 210.

Next, the top electrode 230 is formed on the piezoelectric crystal 220.

Of course, in other embodiments, it is also possible to form the top and bottom electrodes respectively on the opposing sides of the piezoelectric crystal and then bond the three as a whole to the back side of the device wafer 100.

In step S400, the connecting structure is formed on the device wafer 100. The connecting structure includes a first connecting member for electrically connecting the bottom electrode and a second connecting member for electrically connecting the top electrode.

The bottom electrode 210 has an extension extending beyond the piezoelectric crystal 220, and the extension of the bottom electrode forms the first connecting member that connects the bottom electrode 210 to the control circuit.

The second connecting member may be formed subsequent to the formation of the piezoelectric crystal 220 and prior to the formation of the top electrode 230. Specifically, a method for forming the second connecting member prior to the formation of the top electrode and electrically connecting it to the top electrode may include the following steps:

Step 1: Forming an encapsulation layer on a surface of the device wafer 100. In this embodiment, the encapsulation layer covers the surface of the device wafer 100, with the piezoelectric crystal 220 being exposed therefrom.

Step 2: Forming a through hole in the encapsulation layer and filling a conductive material in the through hole, thereby resulting in the formation of a conductive plug. The resulting conductive plug is electrically connected to the second interconnecting structure at the bottom and exposed from the encapsulation layer at the top.

Step 3: Forming the top electrode 230 on the device wafer 100 in such a manner that the top electrode 230 covers at least part of the piezoelectric crystal 220 and extends therefrom over the top of the conductive plug and thus come into electrical connection with the conductive plug. That is, the extension of the top electrode 230 extending beyond the piezoelectric crystal is directly electrically connected to the conductive plug.

Alternatively, in step 3, after the top electrode 230 is formed on the piezoelectric crystal 220, an interconnecting wire may be formed on the top electrode 230 so as to extend beyond the top electrode over the top of the conductive plug. In this way, the top electrode is electrically connected to the conductive plug via the interconnecting wire. That is, the electrical connection between the top electrode 230 and the conductive plug is accomplished by the interconnecting wire.

Bonding the substrate 300 to the device wafer 100 in step S500 of this embodiment may include: applying an adhesive layer to the device wafer 100 in such a manner that the surface of the piezoelectric crystal is exposed from the adhesive layer; and then bonding the device wafer 100 and the substrate 300 together by means of the adhesive layer.

The bonding may be so carried out that the upper cavity in the substrate 300 is located on the side of the piezoelectric crystal 220 away from the lower cavity. The upper cavity may be broader than the piezoelectric crystal so that the piezoelectric crystal can be accommodated within the upper cavity.

### Embodiment 3

Differing from Embodiments 1 and 2 in which the top electrode, piezoelectric crystal and bottom electrode of the piezoelectric vibrator are all formed either on the substrate or on the device wafer, in accordance with Embodiment 3, the top electrode and piezoelectric crystal are formed on the substrate, while the bottom electrode is formed on the device wafer.

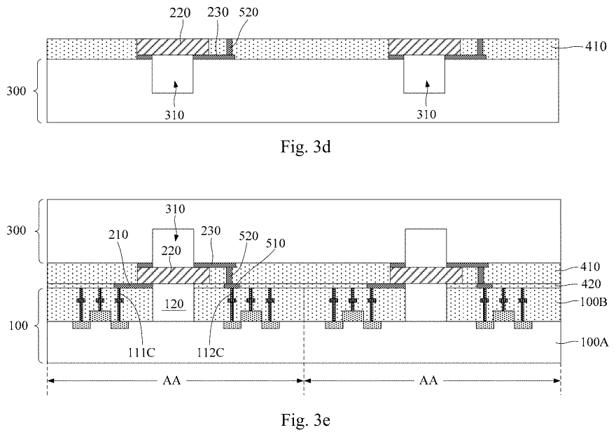

FIGS. 3a to 3e are schematic representations of structures resulting from steps in the method for integrating a crystal resonator with a control circuit according to Embodiment 3 of the present invention. In the following, steps for forming the crystal resonator will be described in detail with reference to the figures.

With particular reference to FIG. 3a, in step S100 and step S300, the device wafer 100 containing the control circuit is provided, and the bottom electrode 210 is formed on the surface of the device wafer 100 so that it is positioned around the lower cavity 120 and electrically connected to the control circuit. The bottom electrode may be formed using a vapor deposition or thin-film deposition process.

Specifically, the bottom electrode 210 covers the first interconnecting structure in the first circuit 111 and thus comes into electrical connection with the first circuit 111. In addition, during the formation of the bottom electrode 210, an interconnecting wire 510 may be formed on the device wafer 100 to cover the second interconnecting structure in the second circuit 112 and thus comes into connection with the second circuit 112.

In addition, subsequent to the formation of the bottom electrode 210, the method may further include forming a second encapsulation layer 420 on the device wafer 100, and the second encapsulation layer 420 has a surface that is not higher than that of the bottom electrode 210 so that the bottom electrode 210 remains exposed. In this embodiment, the surface of the second encapsulation layer 420 is also not higher than that of the interconnecting wire 510 so that the interconnecting wire 510 is also exposed. In this way, the subsequent bonding process may be so performed that the bottom electrode 210 is positioned on one side of the piezoelectric crystal, with the interconnecting wire 510 being electrically connected to the top electrode located on the other side of the piezoelectric crystal.

The formation of the second encapsulation layer 420 may involve a planarization process for making the surface of the second encapsulation layer 420 flush with that of the bottom electrode 210. In this way, a significant improved surface flatness can be provided to the device wafer 100, which is favorable to the subsequent bonding process.

With continued reference to FIG. 3b, in this embodiment, subsequent to the successive formation of the bottom electrode 210 and the second encapsulation layer 420, the lower cavity 120 can be formed by successively etching through the second encapsulation layer 420 and the dielectric layer 100B so that the bottom electrode 210 is positioned around the lower cavity 120.

In step S200 and step S300, referring to FIG. 3c, the substrate 300 is provided, and the top electrode 230 and piezoelectric crystal 220 are successively formed thereon above the upper cavity. The top electrode may be formed using a vapor deposition process or a thin-film deposition process, followed by bonding the piezoelectric crystal to the top electrode.

Specifically, the top electrode 230 is positioned around the upper cavity 310 and will be electrically connected to the interconnecting wire 510 on the device wafer 100 and hence to the second interconnecting structure in the second circuit 112 in a subsequent process. Moreover, the piezoelectric crystal 220 may be so positioned that a central portion thereof is in positional correspondence with the upper cavity 310 in the substrate 300, with its peripheral edge portions residing on top edges of the top electrode 230. Further, an extension of the top electrode 230 may extend beyond the piezoelectric crystal 220 thereunder.

With continued reference to FIG. 3c, in this embodiment, subsequent to the formation of the piezoelectric crystal 220, the method may further include forming a first encapsulation layer 410 on the substrate 300 to cover the substrate 300 and the extension of the top electrode 230. The first encapsulation layer 410 may have a surface not higher than that of the piezoelectric crystal 220 so that the piezoelectric crystal 220 is exposed therefrom.

Similarly, in this embodiment, the formation of the first encapsulation layer 410 may also involve a planarization process for making the surface of the first encapsulation layer 410 flush with that of the piezoelectric crystal 220. In this way, the substrate 300 may be provided with a flatter surface, which is favorable to the subsequent bonding process.

In step S400, referring to FIG. 3d, the connecting structure including the first connecting member and the second connecting member may be formed on the device wafer or the substrate.

The connecting structure can bring the top electrode 230 on the substrate 300 into electrical connection with the second circuit 112 in the device wafer 100 in the subsequent bonding process. It is to be noted that, in this embodiment, the first connecting member is directly made up of the extension of the bottom electrode 210. The second connecting member can bring the extension of the top electrode 230 that is buried within the first encapsulation layer 410 into electrical connection with the second interconnecting structure in the second circuit 112.

With reference to FIG. 3d, a method for forming the second connecting member that connects the top electrode 230 to the second circuit 112 may include the steps below.

At first, an encapsulation layer is formed on the surface of the substrate 100. In this embodiment, the encapsulation layer is made up of the aforementioned first encapsulation layer 410.

Next, the encapsulation layer is etched so that a through hole is formed therein. In this embodiment, the first encapsulation layer 410 is etched, and the extension of the top electrode 230 is exposed in the resulting through hole. A conductive material is then filled in the through hole, resulting in the formation of a conductive plug 520, which is exposed at the top from the surface of the first encapsulation layer 410. Specifically, the conductive plug 520 is connected to the extension of the top electrode 230. As a result, the top electrode 230 is brought into electrical connection with the second circuit 112 by the conductive plug 520 and the interconnecting wire 510.

In step S500, referring to FIG. 3e, the substrate 300 is then bonded to the device wafer 100 so that the lower cavity 120 is positioned on the side of the piezoelectric crystal 220 away from the upper cavity 310. Accordingly, the bottom electrode 210 on the device wafer 100 is located on the side of the piezoelectric crystal 520 away from the top electrode 230.

In this embodiment, the bonding of the substrate 300 to the device wafer 100 may include: applying an adhesive layer to the substrate 300 in such a manner that the surface of the piezoelectric crystal 220 is exposed from the adhesive layer; and then bonding the device wafer and the substrate together by means of the adhesive layer.

Specifically, the bonding of the substrate 300 to the device wafer 100 may bring the interconnecting wire 510 on the device wafer 100 that is connected to the second circuit 112 into electrical contact with the conductive plug 520 on the substrate 300 that is connected to the top electrode 230, achieving electrical connection of the top electrode 230 to the second circuit 112.

A crystal resonator corresponding to the above method according to an embodiment will be described below with reference to FIG. 2g or 3e. The crystal resonator includes:

a device wafer 100, in which the control circuit and a lower cavity 120 are formed, the lower cavity 120 having an opening facing the substrate 300;

a substrate 300, which is bonded to the front side of the device wafer 100, and in which an upper cavity 310 is formed, the upper cavity 310 having an opening facing the device wafer 100, i.e., opposing the opening of the lower cavity 120;

a piezoelectric vibrator 200 comprising a bottom electrode 210, a piezoelectric crystal 220 and a top electrode 230, the piezoelectric vibrator 200 sandwiched between the device wafer 100 and the substrate 300 so that the lower and upper cavities 120, 210 are on opposing sides of the piezoelectric vibrator 200;

a connecting structure arranged between the device wafer 100 and the substrate 300, the connecting structure electrically connecting both the bottom and top electrodes 210, 230 of the piezoelectric vibrator to the control circuit.

Thus, the integration of the crystal resonator with the control circuit is accomplished by utilizing planar fabrication processes to form the lower cavity 120 in the device wafer 100 and the upper cavity 310 in the substrate 300 and by bonding the device wafer 100 and the substrate 300 together so that the upper and lower cavities 120, 310 are in positional correspondence with each other on opposing sides of the piezoelectric crystal 220 to allow the piezoelectric crystal 220 to oscillate within the upper and lower cavities 310, 120 under the control of the control circuit. This helps on-chip modulation for correcting raw deviations of the crystal resonator such as temperature and frequency drifts. Further, the crystal resonator fabricated using semiconductor processes is more compact in size and is thus less power-consuming.

With continued reference to FIG. 2g or 3e, the control circuit may include first and second circuits 111, 112, which are electrically connected to the bottom and top electrodes 210, 230, respectively.

The first circuit 111 may include a first transistor 111T and a first interconnecting structure 111C. The first transistor 111T may be buried within the device wafer 100, and the first interconnecting structure 111C may be connected to the first transistor 111T and extend to the surface of the device wafer 100 to be electrically connected to the bottom electrode 210.

The second circuit 112 may include a second transistor 112T and second interconnecting structure 112C. The second transistor 112T may be buried within the device wafer 100, and the second interconnecting structure 112C may be connected to the second transistor 112T and extend to the surface of the device wafer 100, so as to be electrically connected with the top electrode 230.

In order to enable vibration of the piezoelectric crystal 220, an electrical signal may be applied to the top and bottom electrodes 230, 210 to create an electric field therebetween, which causes a mechanical deformation of the piezoelectric crystal 220. Exemplary materials for the top and bottom electrodes 230, 210 may include, for example, silver. Exemplary materials for the piezoelectric crystal 220 may include, for example, quartz.

In addition, the connecting structure may include a first connecting member that connects the first interconnecting structure 111C to the bottom electrode 210 of the piezoelectric vibrator and a second connecting member that connects the second interconnecting structure 112C to the top electrode 230 of the piezoelectric vibrator.

In this embodiment, the bottom electrode 210 is arranged around the lower cavity 120 and has an extension that laterally extends beyond the piezoelectric crystal 220 over the first interconnecting structure 111C in the first circuit, thus coming into electrical connection with the first interconnecting structure 111C. Therefore, it can be considered that the extension of the bottom electrode makes up the first connecting member.

The top electrode 230 is arranged around the upper cavity 310 and has an extension laterally extending beyond the piezoelectric crystal 220. The extension of the top electrode 230 may be electrically connected to the second interconnecting structure 112C in the second circuit 112 via the second connecting member.

Specifically, an encapsulation layer may be arranged between the device wafer 100 and the substrate 300 such as to cover side surfaces of the piezoelectric crystal 220 and both the extensions of the top and bottom electrodes. The second connecting member may include a conductive plug 520, which may extend through the encapsulation layer so as to be connected to the extension of the top electrode at one end and to the second circuit 112 at the other end. In this way, electrical connection between the top electrode 230 and the second circuit 112 can be accomplished with the conductive plug 520.

In one particular embodiment, for example, as shown in FIG. 2g, the encapsulation layer includes a first encapsulation layer 410 and a second encapsulation layer 420, which are stacked together in such a manner that the first encapsulation layer 410 is closer to the substrate 300 than the second encapsulation layer 420. A surface of the first encapsulation layer 410 facing the device wafer 100 is flush with a surface of the piezoelectric crystal 220 facing the device wafer 100, and a surface of the second encapsulation layer 420 facing the device wafer 100 is flush with a surface of the bottom electrode 210 facing the device wafer 100. It can be considered that the surface of the second encapsulation layer 420 facing the device wafer 100 provides a bonding surface for the substrate 300.

In this embodiment, the conductive plug 520 extends through the first encapsulation layer 410 and the second encapsulation layer 420. As a result of the bonding of the substrate 300 to the device wafer 100, the conductive plug 520 extending up to the surface of the device wafer 100 is connected to the extension of the top electrode at one end and to the second interconnecting structure in the second circuit 112 at the other end.

Of course, in other embodiments, the second connecting member may further include an interconnecting wire, which covers the top electrode 230 at one end and covers the conductive plug 520 at the other end.

In such embodiments, in the encapsulation layer, the surface of the first encapsulation layer 410 facing the device wafer 100 may be made flush with the surface of the piezoelectric crystal 220 facing the device wafer 100 so as to be able to provide a bonding surface for the substrate 300. Moreover, a surface of the second encapsulation layer 420 facing the substrate 300 may be made flush with a surface of the bottom electrode 210 facing the substrate 100 so as to be able to provide a bonding surface for the device wafer 100.

With continued reference to FIG. 2g or 3e, in this embodiment, the device wafer 100 includes a substrate wafer 100A and a dielectric layer 100B. The first and second transistors 111T, 112T may be both formed on the substrate wafer 100A, and the dielectric layer 100B may be formed on the substrate wafer 100A and cover both the first and second transistors 111T, 112T. Each of the first and second interconnecting structures 111C, 112C may be formed in the dielectric layer 100B.

In summary, in the method for integrating the crystal resonator with the control circuit according to the present invention, the lower cavity is formed in the device wafer, and the upper cavity is formed in the substrate. A bonding process is employed to bond the substrate to the device wafer in such a manner that the piezoelectric vibrator is sandwiched between the device wafer and the substrate, with the lower and upper cavities being in positional correspondence with each other on opposing sides of the piezoelectric vibrator to provide a space where the piezoelectric vibrator can vibrate. Apparently, compared with traditional crystal resonators (e.g., surface-mount ones), the proposed crystal resonator fabricated using planar fabrication processes is more compact in size and hence less power-consuming. Moreover, it is able to integrate with the control circuit and other semiconductor components more easily with a higher degree of integration.

The embodiments disclosed herein are described in a progressive manner, with the description of each embodiment focusing on its differences from others. Reference can be made between the embodiments for their identical or similar parts.

The description presented above is merely that of a few preferred embodiments of the present invention without limiting the scope thereof in any sense. Any and all changes and modifications made by those of ordinary skill in the art based on the above teachings fall within the scope as defined in the appended claims.

1. A method for integrating a crystal resonator with a control circuit, comprising:
providing a device wafer in which the control circuit is formed, and etching the device wafer to form a lower cavity for the crystal resonator;
providing a substrate and etching the substrate to form, for the crystal resonator, an upper cavity in positional correspondence with the lower cavity;
forming a piezoelectric vibrator comprising a top electrode, a piezoelectric crystal and a bottom electrode, which are formed either on a front side of the device wafer or on the substrate;
forming a connecting structure on the device wafer or on the substrate; and
bonding the substrate to the front side of the device wafer such that the piezoelectric vibrator is situated between the device wafer and the substrate, with the upper and lower cavities being located on opposing sides of the piezoelectric vibrator, and electrically connecting both the top and bottom electrodes of the piezoelectric vibrator to the control circuit through the connecting structure.

2. The method for integrating a crystal resonator with a control circuit according to claim 1, wherein the piezoelectric vibrator is formed on the device wafer or on the substrate; or
wherein the bottom electrode of the piezoelectric vibrator is formed on the device wafer, and the top electrode and piezoelectric crystal of the piezoelectric vibrator are sequentially formed on the substrate; or
wherein the bottom electrode and piezoelectric crystal of the piezoelectric vibrator are sequentially formed on the device wafer and the top electrode of the piezoelectric vibrator is formed on the substrate.

3. The method for integrating a crystal resonator with a control circuit according to claim 1, wherein the device wafer comprises a substrate wafer and a dielectric layer formed on the substrate wafer, and wherein the lower cavity is formed in the dielectric layer;
wherein the substrate wafer is a silicon-on-insulator substrate comprising a base layer, a buried oxide layer and a top silicon layer, which are sequentially stacked from a back side to the front side of the device wafer, and wherein the lower cavity further extends into the buried oxide layer from the dielectric layer.

4. (canceled)

5. The method for integrating a crystal resonator with a control circuit according to claim 1, wherein the upper cavity has a size greater than a size of the piezoelectric crystal, and the substrate is bonded to the device wafer so that at least part of the piezoelectric crystal is inside the upper cavity; or
wherein the upper cavity has a size smaller than a size of the piezoelectric crystal, and the substrate is bonded to the device wafer so that the piezoelectric having peripheral edge portions resting on a surface of the substrate crystal covers and closes an opening of the upper cavity.

6. The method for integrating a crystal resonator with a control circuit according to claim 2, wherein forming the piezoelectric vibrator on the device wafer comprises: forming the bottom electrode at a predetermined position on a surface of the device wafer; bonding the piezoelectric crystal to the bottom electrode; and forming the top electrode on the piezoelectric crystal; or
forming the top electrode and the bottom electrode of the piezoelectric vibrator on the piezoelectric crystal; and bonding the top electrode, the piezoelectric crystal and the bottom electrode as a whole to the device wafer;
wherein the formation of the bottom electrode comprises a vapor deposition process or a thin-film deposition process, and wherein the formation of the top electrode comprises a vapor deposition process or a thin-film deposition process.

7. The method for integrating a crystal resonator with a control circuit according to claim 2, wherein forming the piezoelectric vibrator on the substrate comprises:
forming the top electrode at a predetermined position on a surface of the substrate; bonding the piezoelectric crystal to the top electrode; and forming the bottom electrode on the piezoelectric crystal; or
forming the top electrode and the bottom electrode of the piezoelectric vibrator on the piezoelectric crystal; and bonding the top electrode, the piezoelectric crystal and the bottom electrode as a whole to the substrate;
wherein the formation of the bottom electrode comprises a vapor deposition process or a thin-film deposition process, and wherein the formation of the top electrode comprises a vapor deposition process or a thin-film deposition process.

8. (canceled)

9. The method for integrating a crystal resonator with a control circuit according to claim 2, wherein the top electrode is formed on the substrate, and the bottom electrode is formed on the device wafer, wherein each of the top and bottom electrodes is formed using a vapor deposition process or a thin-film deposition process, and wherein the piezoelectric crystal is bonded to the top electrode or the bottom electrode.

10. The method for integrating a crystal resonator with a control circuit according to claim 1, wherein the control circuit comprises a first interconnecting structure and a second interconnecting structure, and the connecting structure comprises a first connecting member and a second connecting member,
wherein the first connecting member is connected to the first interconnecting structure and the bottom electrode of the piezoelectric vibrator, and the second connecting member is connected to the second interconnecting structure and the top electrode of the piezoelectric vibrator.

11. The method for integrating a crystal resonator with a control circuit according to claim 10, wherein subsequent to the bonding of the substrate to the device wafer, the bottom electrode is formed on a surface of the device wafer, and has an extension that extends beyond the piezoelectric crystal thereunder to come into electrical connection with the first interconnecting structure, wherein the extension of the bottom electrode forms the first connecting member.

12. The method for integrating a crystal resonator with a control circuit according to claim 10, wherein the first connecting member is formed on the device wafer prior to the formation of the bottom electrode on the device wafer, and is electrically connected to the first interconnecting structure and configured for electrical connection with the bottom electrode subsequently formed on the device wafer.

13. The method for integrating a crystal resonator with a control circuit according to claim 12, wherein the first connecting member comprises a rewiring layer connected to the first interconnecting structure, and wherein the rewiring layer is brought into electrical connection with the bottom electrode subsequent to the formation of the bottom electrode.

14. The method for integrating a crystal resonator with a control circuit according to claim 10, wherein the piezoelectric crystal is formed on the device wafer, and wherein the second connecting member is formed on the device wafer prior to the formation of the top electrode on the device wafer, and is electrically connected to the second interconnecting structure and configured for electrical connection with the top electrode subsequently formed on the device wafer;
wherein the formation of the second connecting member comprises:
forming a encapsulation layer on a surface of the device wafer;
forming a through hole in the encapsulation layer and filling a conductive material in the through hole, to form a conductive plug having a bottom portion electrically connected to the second interconnecting structure and a top portion exposed from the encapsulation layer; and
forming, on the device wafer, the top electrode which extends beyond the piezoelectric crystal to the top portion of the conductive plug to bring the top electrode into electrical connection with the conductive plug, or forming, on the device wafer, the top electrode, then forming an interconnecting wire on the top electrode, the interconnecting wire extending from the top electrode over the conductive plug, so that the top electrode is in electrical connection with the conductive plug.

15. (canceled)

16. The method for integrating a crystal resonator with a control circuit according to claim 10, wherein the top electrode and the piezoelectric crystal are successively formed on the substrate, and wherein the second connecting member is formed on the substrate and electrically connected to the top electrode prior to the bonding of the substrate to the device wafer and is brought into electrical connection with the second interconnecting structure subsequent to the bonding of the substrate to the device wafer;
wherein the formation of the second connecting member comprises:
forming a encapsulation layer on a surface of the substrate;
forming a through hole in the encapsulation layer to expose the top electrode, and filling a conductive material in the through hole to form a conductive plug having an end electrically connected the top electrode; and
electrically connecting a further end of the conductive plug to the second interconnecting structure as a result of the bonding of the substrate to the device wafer.

17. (canceled)

18. The method for integrating a crystal resonator with a control circuit according to claim 10, wherein the control circuit further comprises a first transistor connected to the first interconnecting structure and a second transistor connected to the second interconnecting structure.

19. The method for integrating a crystal resonator with a control circuit according to claim 1, wherein the bonding of the substrate to the device wafer comprises:
forming an adhesive layer on the device wafer and/or the substrate, and bonding the substrate with the device wafer by using the adhesive layer;
wherein a surface of the piezoelectric crystal is exposed from the adhesive layer.

20. (canceled)

21. (canceled)

22. (canceled)

23. An integrated structure of a crystal resonator and a control circuit, comprising:
a device wafer in which the control circuit and a lower cavity are formed;
a substrate, which is bonded to the front side of the device wafer, and in which an upper cavity is formed, the upper cavity having an opening opposing an opening of the lower cavity;
a piezoelectric vibrator comprising a bottom electrode, a piezoelectric crystal and a top electrode, the piezoelectric vibrator arranged between the device wafer and the substrate, with the lower and upper cavities being positioned on opposing sides of the piezoelectric vibrator; and
a connecting structure disposed between the device wafer and the substrate, the connecting structure electrically connecting both the bottom and top electrodes of the piezoelectric vibrator to the control circuit.

24. The integrated structure of a crystal resonator and a control circuit according to claim 23, wherein the device wafer comprises a substrate wafer and a dielectric layer formed on the substrate wafer;
wherein the substrate wafer is a silicon-on-insulator substrate comprising a base layer, a buried oxide layer and a top silicon layer, which are sequentially stacked from a back side to the front side of the substrate wafer, and wherein the lower cavity is formed in the dielectric layer and extends from the dielectric layer to the buried oxide layer.

25. (canceled)

26. The integrated structure of a crystal resonator and a control circuit according to claim 23, wherein the control circuit comprises a first interconnecting structure and a second interconnecting structure, and the connecting structure comprises a first connecting member and a second connecting member,
wherein the first connecting member is connected to the first interconnecting structure and the bottom electrode of the piezoelectric vibrator, and the second connecting member is connected to the second interconnecting structure and the top electrode of the piezoelectric vibrator.

27. The integrated structure of a crystal resonator and a control circuit according to claim 26, wherein the bottom electrode extends beyond the piezoelectric crystal thereunder to come into electrical connection with the first interconnecting structure, and the extension of the bottom electrode beyond the piezoelectric crystal constitutes the first connecting member; or
wherein the second connecting member comprises a conductive plug having an end electrically connected to the top electrode and a further end electrically connected to the second interconnecting structure; or
wherein the second connecting structure comprises a conductive plug and an interconnecting wire, wherein the interconnecting wire is formed on a surface of the device wafer and is electrically connected to the second interconnecting structure, and the conductive plug has an end electrically connected to the top electrode and a further end electrically connected to the interconnecting wire.

28. (canceled)

29. (canceled)

30. The integrated structure of a crystal resonator and a control circuit according to claim 26, wherein the control circuit further comprises a first transistor connected to the first interconnecting structure and a second transistor connected to the second interconnecting structure.
